(19) United States
(12) Patent Application Publication
(10) Pub. No.: US 2006/0094180 A1
(43) Pub. Date: May 4, 2006

(54) Method for making a semiconductor device with a high-k gate dielectric layer and a silicide gate electrode

(75) Inventors: Mark L. Doczy, Beaverton, OR (US); Justin K. Brask, Portland, OR (US); Jack Kavalieros, Portland, OR (US); Matthew V. Metz, Hillsboro, OR (US); Suman Datta, Beaverton, OR (US); Robert S. Chau, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Intel Corporation

(21) Appl. No.: 10/980,522

(22) Filed: Nov. 2, 2004

(51) Int. Cl. H01L 21/8238

(52) U.S. Cl. 438/199

(57) ABSTRACT

A method for making a semiconductor device is described. That method comprises forming a high-k gate dielectric layer on a substrate, forming a barrier layer on the high-k gate dielectric layer, and forming a fully silicided gate electrode on the barrier layer.

### FIELD OF THE INVENTION

The present invention relates to semiconductor devices, in particular, those with high-k gate dielectric layers and silicide gate electrodes.

### BACKGROUND OF THE INVENTION

Complementary metal oxide semiconductor (“CMOS”) devices with very thin gate dielectrics made from silicon dioxide may experience unacceptable gate leakage currents. Forming the gate dielectric from certain high-k dielectric materials, instead of silicon dioxide, can reduce gate leakage. When, however, a fully silicided gate electrode is formed directly on such a dielectric, interaction between the gate electrode and the dielectric may cause Fermi level pinning. As a result, a transistor with a fully silicided gate electrode that is formed directly on a high-k gate dielectric may have a relatively high threshold voltage.

Accordingly, there is a need for an improved process for forming a semiconductor device that includes a high-k gate dielectric. There is a need for such a process that forms a device with both a fully silicided gate electrode and a high-k gate dielectric that does not demonstrate an undesirably high threshold voltage. The present invention provides such a method.

### BRIEF DESCRIPTION OF THE DRAWINGS

FIGS. 1a-1d represent cross-sections of structures that may be formed when carrying out an embodiment of the method of the present invention.

FIGS. 2a-2d represent cross-sections of structures that may be formed when carrying out a second embodiment of the method of the present invention.

Features shown in these figures are not intended to be drawn to scale.

### DETAILED DESCRIPTION OF THE PRESENT INVENTION

A method for making a semiconductor device is described. That method comprises forming a high-k gate dielectric layer on a substrate, forming a barrier layer on the high-k gate dielectric layer, and forming a fully silicided gate electrode on the barrier layer. In the following description, a number of details are set forth to provide a thorough understanding of the present invention. It will be apparent to those skilled in the art, however, that the invention may be practiced in many ways other than those expressly described here. The invention is thus not limited by the specific details disclosed below.

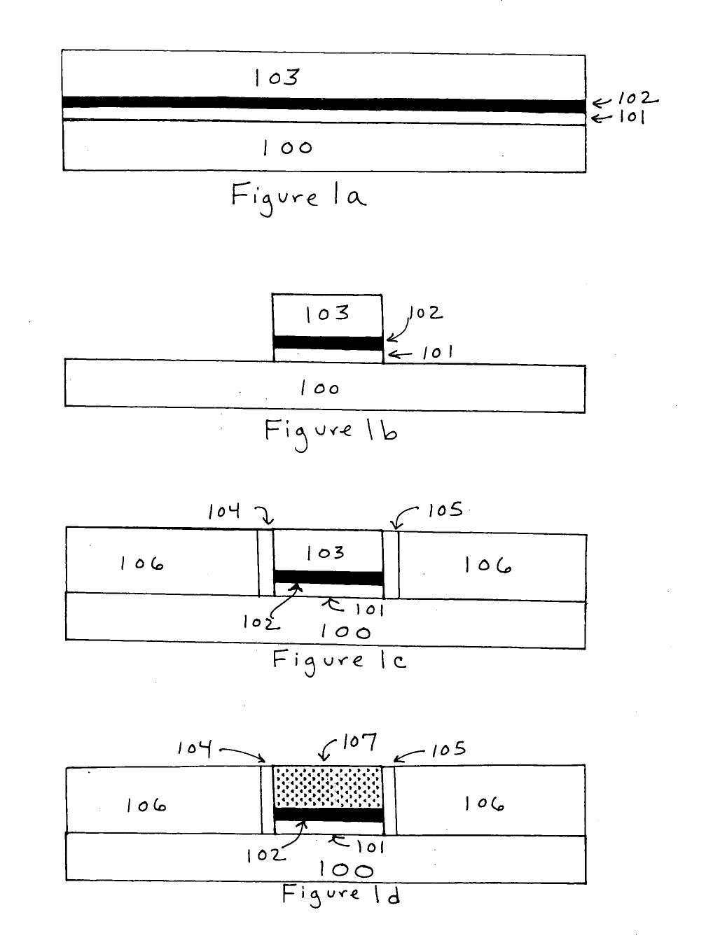

FIGS. 1a-1d represent cross-sections of structures that may be formed when carrying out an embodiment of the method of the present invention. As FIG. 1a illustrates, in this embodiment high-k gate dielectric layer 101 is formed on substrate 100, barrier layer 102 is formed on high-k gate dielectric layer 101, and polysilicon layer 103 is formed on barrier layer 102. Substrate 100 may comprise any material that may serve as a foundation upon which a semiconductor device may be built.

Some of the materials that may be used to make high-k gate dielectric layer 101 include: hafnium oxide, hafnium silicon oxide, lanthanum oxide, lanthanum aluminum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate. Particularly preferred are hafnium oxide, zirconium oxide, and aluminum oxide. Although a few examples of materials that may be used to form high-k gate dielectric layer 101 are described here, that layer may be made from other materials.

High-k gate dielectric layer 101 may be formed on substrate 100 using a conventional deposition method, e.g., a conventional chemical vapor deposition (“CVD”), low pressure CVD, or physical vapor deposition (“PVD”) process. Preferably, a conventional atomic layer CVD process is used. In such a process, a metal oxide precursor (e.g., a metal chloride) and steam may be fed at selected flow rates into a CVD reactor, which is then operated at a selected temperature and pressure to generate an atomically smooth interface between substrate 100 and high-k gate dielectric layer 101. The CVD reactor should be operated long enough to form a layer with the desired thickness. In most applications, high-k gate dielectric layer 101 should be less than about 60 angstroms thick, and more preferably between about 5 angstroms and about 40 angstroms thick.

If high-k gate dielectric layer 101 comprises an oxide, it may manifest oxygen vacancies at random surface sites and unacceptable impurity levels, depending upon the process used to make it. It may be desirable to remove certain impurities from layer 101, and to oxidize it to generate a layer with a nearly idealized metal:oxygen stoichiometry, after layer 101 is deposited.

Barrier layer 102 preferably is electrically conducting and workfunction transparent. In one embodiment, barrier layer 102 may comprise a metal nitride, e.g., titanium nitride or tantalum nitride. Barrier layer 102 may be formed on high-k gate dielectric layer 101 using a conventional CVD or PVD process, as will be apparent to those skilled in the art. Barrier layer 102 must be sufficiently thick to prevent a fully silicided gate electrode (to be formed on barrier layer 102) from interacting with high-k gate dielectric layer 101 to cause undesirable Fermi level pinning. That thickness should be optimized to ensure that barrier layer 102 does not significantly affect the device's threshold voltage, which preferably will be set by the subsequently formed fully silicided gate electrode's workfunction. In many applications, a barrier layer that is between about 5 angstroms and about 50 angstroms thick (and more preferably that is between about 10 angstroms and about 20 angstroms thick) may mitigate Fermi level pinning while remaining workfunction transparent.

Polysilicon layer 103 may be formed on barrier layer 102 using a conventional deposition process, and preferably is between about 100 and about 2,000 angstroms thick, and more preferably is between about 500 and about 1,600 angstroms thick. At this stage in the process, polysilicon layer 103 may be undoped, doped n-type (e.g., with arsenic, phosphorus or another n-type material) or doped p-type, e.g., with boron.

After forming the FIG. 1a structure, polysilicon layer 103, barrier layer 102, and high-k gate dielectric layer 101 are etched to generate the structure that FIG. 1b illustrates. Conventional patterning and etching processes may be used, as will be apparent to those skilled in the art. Subsequently, spacers 104 and 105 are formed adjacent to that structure, and dielectric layer 106 is formed adjacent to those spacers. Spacers 104 and 105 preferably comprise silicon nitride, while dielectric layer 106 may comprise silicon dioxide, or a low-K material. Because those skilled in the art are familiar with the conventional process steps that may be used to form such structures, they will not be described in further detail here. As shown, dielectric layer 106 has been polished back, e.g., via a conventional chemical mechanical polishing (“CMP”) operation, to expose polysilicon layer 103 and to generate the FIG. 1c structure. Although not shown, that structure may include many other features (e.g., a silicon nitride etch stop layer, source and drain regions, and one or more buffer layers) that may be formed using conventional processes.

After forming the FIG. 1c structure, substantially all of polysilicon layer 103 (and preferably all of that layer) is converted to silicide 107, as shown in FIG. 1d. Fully silicided gate electrode 107 may comprise, for example, nickel silicide, cobalt silicide, titanium silicide, or a combination of those materials. Polysilicon layer 103 may be converted to fully silicided gate electrode 107 by depositing an appropriate metal over the entire structure, then applying heat at a sufficient temperature for a sufficient time to generate a metal silicide (e.g., NiSi) from polysilicon layer 103.

In a preferred embodiment, silicide 107 is formed by first sputtering an appropriate metal (e.g., nickel) over the entire structure, including the exposed surface of layer 103. To cause silicide 107 to extend completely through polysilicon layer 103, it may be necessary to follow that sputter operation with a high temperature anneal, e.g., a rapid thermal anneal that takes place at a temperature of at least about 450° C. When forming nickel silicide, the anneal preferably takes place at a temperature that is between about 500° C. and about 550° C. When forming cobalt silicide, the anneal preferably takes place at a temperature that is at least about 600° C.

A conventional CMP step may be applied to remove excess metal from the structure after creating silicide 107—dielectric layer 106 serving as a polish stop. Silicide 107 may serve as a fully silicided gate electrode that is suitable for use as a fully silicided PMOS gate electrode or a fully silicided NMOS gate electrode. Whether silicide 107 may serve as a fully silicided PMOS gate electrode or a fully silicided NMOS gate electrode may depend upon the doping treatment polysilicon layer 103 received, the metal used to generate the silicide, and the process for creating it. In some embodiments, the process of the present invention may be used to generate a CMOS device that includes both fully silicided PMOS and fully silicided NMOS gate electrodes.

The presence of barrier layer 102 between high-k gate dielectric layer 101 and fully silicided gate electrode 107 may prevent undesirable interaction between the gate electrode and the dielectric, which may cause Fermi level pinning. As a result, the process of the present invention may enable a device with both a fully silicided gate electrode and a high-k gate dielectric that does not demonstrate an undesirably high threshold voltage.

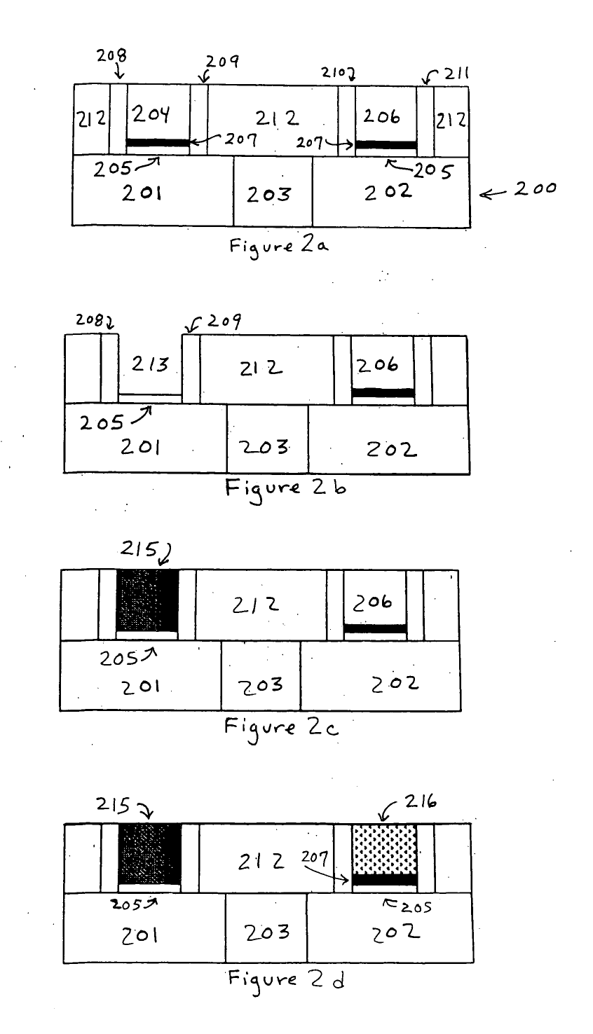

FIGS. 2a-2d illustrate structures that may be formed, when carrying out a second embodiment of the method of the present invention. In this embodiment, a CMOS device is formed that includes a metal NMOS gate electrode and a fully silicided PMOS gate electrode. FIG. 2a represents an intermediate structure that may be formed when making a CMOS device. That structure includes first part 201 and second part 202 of substrate 200. Isolation region 203 separates first part 201 from second part 202. High-k gate dielectric layer 205 is formed on substrate 200, and barrier layer 207 is formed on high-k gate dielectric layer 205. A polysilicon layer is formed on barrier layer 207. First part 204 of that polysilicon layer is bracketed by a pair of sidewall spacers 208 and 209, and second part 206 of that polysilicon layer is bracketed by a pair of sidewall spacers 210 and 211. Dielectric 212 lies next to the sidewall spacers.

Substrate 200 may comprise any material that may serve as a foundation upon which a semiconductor device may be built. Isolation region 203 may comprise silicon dioxide, or other materials that may separate the transistor's active regions. High-k gate dielectric layer 205 and barrier layer 207 may comprise any of the materials identified above, and may be formed using conventional processes, as described above. First and second parts 204 and 206 of the polysilicon layer preferably are each between about 100 and about 2,000 angstroms thick, and more preferably are between about 500 and about 1,600 angstroms thick.

First part 204 may be undoped or doped with arsenic, phosphorus or another n-type material. In a preferred embodiment, first part 204 is doped n-type while second part 206 is doped p-type, e.g., by doping second part 206 with boron. When doped with boron, p-type polysilicon layer 206 should include that element at a sufficient concentration to ensure that a subsequent wet etch process, for removing first part 204, will not remove a significant amount of p-type polysilicon layer 206. Spacers 208, 209, 210, and 211 preferably comprise silicon nitride, while dielectric 212 may comprise silicon dioxide, or a low-K material.

Conventional process steps, materials, and equipment may be used to generate the FIG. 2a structure, as will be apparent to those skilled in the art. As shown, dielectric 212 may be polished back, e.g., via a conventional CMP operation, to expose first and second parts 204 and 206 of the polysilicon layer. Although not shown, the FIG. 2a structure may include many other features (e.g., a silicon nitride etch stop layer, source and drain regions, and one or more buffer layers) that may be formed using conventional processes.

After forming the FIG. 2a structure, first part 204 may be removed. In a preferred embodiment, first part 204 is removed by applying a wet etch process that is selective for first part 204 over p-type polysilicon layer 206 to remove first part 204 without removing significant portions of p-type polysilicon layer 206. Such a wet etch process may comprise exposing first part 204 to an aqueous solution that comprises a source of hydroxide for a sufficient time at a sufficient temperature to remove substantially all of part 204. That source of hydroxide may comprise between about 2 and about 30 percent ammonium hydroxide or a tetraalkyl ammonium hydroxide, e.g., tetramethyl ammonium hydroxide (“TMAH”), by volume in deionized water.

For example, first part 204 may be selectively removed by exposing it to a solution, which is maintained at a temperature between about 15° C. and about 90° C. (and preferably below about 40° C.), that comprises between about 2 and about 30 percent ammonium hydroxide by volume in deionized water. During that exposure step, which preferably lasts at least one minute, it may be desirable to apply sonic energy at a frequency of between about 10 KHz and about 2,000 KHz, while dissipating at between about 1 and about 10 watts/cm².

In a particularly preferred embodiment, first part 204, with a thickness of about 1,350 angstroms, may be selectively removed by exposing it at about 25° C. for about 30 minutes to a solution that comprises about 15 percent ammonium hydroxide by volume in deionized water, while applying sonic energy at about 1,000 KHz—dissipating at about 5 watts/cm². Such an etch process should remove substantially all of an n-type polysilicon layer without removing a meaningful amount of p-type polysilicon layer 206.

As an alternative, first part 204 may be selectively removed by exposing it for at least one minute to a solution, which is maintained at a temperature between about 60° C. and about 90° C., that comprises between about 20 and about 30 percent TMAH by volume in deionized water, while applying sonic energy. Removing first part 204, with a thickness of about 1,350 angstroms, by exposing it at about 80° C. for about 2 minutes to a solution that comprises about 25 percent TMAH by volume in deionized water, while applying sonic energy at about 1,000 KHz—dissipating at about 5 watts/cm²—may remove substantially all of first part 204 without removing a significant amount of p-type polysilicon layer 206.

After removing first part 204, the underlying part of barrier layer 207 may be removed, e.g., by applying an etch process that is selective for barrier layer 207 over high-k gate dielectric layer 205. Removal of first part 204 and barrier layer 207 generates trench 213—positioned between sidewall spacers 208 and 209, as FIG. 2b illustrates. Although in this embodiment, barrier layer 207 is removed after (or when) removing first part 204 of the overlying polysilicon layer, in alternative embodiments barrier layer 207 may be retained—depending upon the composition of first part 204 and the process used to remove it.

In this embodiment, after removing first part 204 and the underlying part of barrier layer 207, n-type metal layer 215 is formed within trench 213 and on high-k gate dielectric layer 205, creating the FIG. 2c structure. N-type metal layer 215 may comprise any n-type conductive material from which a metal NMOS gate electrode may be derived. Materials that may be used to form n-type metal layer 215 include: hafnium, zirconium, titanium, tantalum, aluminum, and their alloys, e.g., metal carbides that include these elements, i.e., hafnium carbide, zirconium carbide, titanium carbide, tantalum carbide, and aluminum carbide. N-type metal layer 215 may alternatively comprise an aluminide, e.g., an aluminide that comprises hafnium, zirconium, titanium, tantalum, or tungsten.

N-type metal layer 215 may be formed on high-k gate dielectric layer 205 using well known PVD or CVD processes, e.g., conventional sputter or atomic layer CVD processes. As shown, n-type metal layer 215 is removed except where it fills trench 213. Layer 215 may be removed from other portions of the device via an appropriate CMP operation. Dielectric 212 may serve as a polish stop, when layer 215 is removed from its surface. N-type metal layer 215 preferably serves as a metal NMOS gate electrode with a workfunction that is between about 3.9 eV and about 4.2 eV, and that is between about 100 angstroms and about 2,000 angstroms thick, and more preferably is between about 500 angstroms and about 1,600 angstroms thick.

Although FIG. 2c represents a structure in which n-type metal layer 215 fills all of trench 213, in alternative embodiments, n-type metal layer 215 may fill only part of trench 213, with the remainder of the trench being filled with a material that may be easily polished, e.g., tungsten, aluminum, titanium, or titanium nitride. In such an alternative embodiment, n-type metal layer 215, which serves as the workfunction metal, may be between about 50 and about 1,000 angstroms thick—and more preferably at least about 100 angstroms thick.

In the illustrated embodiment, after forming n-type metal layer 215 within trench 213, substantially all of p-type polysilicon layer 206 (and preferably all of that layer) is converted to silicide 216, as shown in FIG. 2d. Fully silicided gate electrode 216 may comprise nickel silicide, cobalt silicide, titanium silicide, a combination of those materials, or any other type of silicide that may yield a high performance fully silicided PMOS gate electrode. P-type polysilicon layer 206 may be converted to fully silicided gate electrode 216 by depositing an appropriate metal over the entire structure, then applying heat at a sufficient temperature for a sufficient time to generate a metal silicide (e.g., NiSi) from p-type polysilicon layer 206.

In a preferred embodiment, suicide 216 is formed by first sputtering an appropriate metal (e.g., nickel) over the entire structure, including the exposed surface of layer 206. To cause suicide 216 to extend completely through p-type polysilicon layer 206, it may be necessary to follow that sputter operation with a high temperature anneal, e.g., a rapid thermal anneal that takes place at a temperature of at least about 450° C. When forming nickel silicide, the anneal preferably takes place at a temperature that is between about 500° C. and about 550° C. When forming cobalt silicide, the anneal preferably takes place at a temperature that is at least about 600° C.

A conventional CMP step may be applied to remove excess metal from the structure after creating silicide 216—dielectric 212 serving as a polish stop. In a preferred embodiment, silicide 216 serves as a fully silicided PMOS gate electrode with a midgap workfunction that is between about 4.3 eV and about 4.8 eV, and that is between about 100 angstroms and about 2,000 angstroms thick, and more preferably is between about 500 angstroms and about 1,600 angstroms thick.

Although a few examples of materials that may be used to form n-type metal layer 215 and silicide 216 are described here, that metal layer and that silicide may be made from many other materials, as will be apparent to those skilled in the art. After forming silicide 216, process steps for completing the device may follow, e.g., forming a capping dielectric layer over the FIG. 2d structure, then forming the device's contacts, metal interconnect, and passivation layer. Because such process steps are well known to those skilled in the art, they will not be described in more detail here.

This second embodiment of the method of the present invention enables a CMOS device that includes a metal NMOS gate electrode and a fully silicided PMOS gate electrode that does not have an undesirably high threshold voltage. Although the embodiments described above provide examples of processes for forming such devices, the present invention is not limited to these particular embodiments.

The semiconductor device of FIG. 2d comprises metal NMOS gate electrode 215 and fully silicided PMOS gate electrode 216 that are formed on high-k gate dielectric layer 205 and barrier layer 207, respectively. High-k gate dielectric layer 205 and barrier layer 207 may comprise any of the materials listed above. Metal NMOS gate electrode 215 may consist entirely of one or more of the n-type metals identified above, or, alternatively, may comprise an n-type workfunction metal that is capped by a trench fill metal. Metal NMOS gate electrode 215 preferably is between about 100 and about 2,000 angstroms thick, and has a workfunction that is between about 3.9 eV and about 4.2 eV. Fully silicided PMOS gate electrode 216 preferably is between about 100 and about 2,000 angstroms thick, has a midgap workfunction that is between about 4.3 eV and about 4.8 eV, and comprises one of the silicides identified above.

Although the semiconductor device of the present invention may be made using the processes set forth in detail above, it may alternatively be formed using other types of processes. For that reason, that semiconductor device is not intended to be limited to devices that may be made using the processes described above.

The method of the present invention may enable a device with both a fully silicided gate electrode and a high-k gate dielectric that does not demonstrate an undesirably high threshold voltage. Although the foregoing description has specified certain steps and materials that may be used in the present invention, those skilled in the art will appreciate that many modifications and substitutions may be made. Accordingly, it is intended that all such modifications, alterations, substitutions and additions be considered to fall within the spirit and scope of the invention as defined by the appended claims.

What is claimed is:

1. A method for making a semiconductor device comprising:
forming a high-k gate dielectric layer on a substrate;
forming a barrier layer on the high-k gate dielectric layer; and
forming a fully silicided gate electrode on the barrier layer.

2. The method of claim 1 wherein the high-k gate dielectric layer comprises a material that is selected from the group consisting of hafnium oxide, hafnium silicon oxide, lanthanum oxide, lanthanum aluminum oxide, zirconium oxide, zirconium silicon oxide, tantalum oxide, barium strontium titanium oxide, barium titanium oxide, strontium titanium oxide, yttrium oxide, aluminum oxide, lead scandium tantalum oxide, and lead zinc niobate.

3. The method of claim 1 wherein the barrier layer is electrically conducting and workfunction transparent.

4. The method of claim 3 wherein the barrier layer comprises a metal nitride.

5. The method of claim 1 wherein the fully silicided gate electrode comprises a material that is selected from the group consisting of nickel silicide, cobalt silicide, and titanium silicide.

6. The method of claim 1 wherein substantially all of a p-type polysilicon layer is converted to silicide to generate the fully silicided gate electrode.

7. The method of claim 1 wherein all of a p-type polysilicon layer is converted to silicide to generate the fully silicided gate electrode.

8. A method for making a semiconductor device comprising:
forming a high-k gate dielectric layer on a substrate;
forming a barrier layer on the high-k gate dielectric layer;
forming a polysilicon layer on the barrier layer;
removing a first part of the polysilicon layer to generate a trench that is positioned between a pair of sidewall spacers;
forming an n-type metal layer within the trench;
depositing a second metal layer on a second part of the polysilicon layer; and
applying heat at a sufficient temperature for a sufficient time to convert substantially all of the second part of the polysilicon layer into a metal silicide.

9. The method of claim 8 wherein the n-type metal layer comprises a material that is selected from the group consisting of hafnium, zirconium, titanium, tantalum, aluminum, a metal carbide, and an aluminide.

10. The method of claim 8 wherein the metal silicide is selected from the group consisting of nickel silicide, cobalt silicide, and titanium silicide.

11. The method of claim 8 wherein the n-type metal layer has a workfunction that is between about 3.9 eV and about 4.2 eV, and the metal silicide has a workfunction that is between about 4.3 eV and about 4.8 eV.

12. The method of claim 8 wherein the second part of the polysilicon layer is a p-type polysilicon layer and the first part of the polysilicon layer is removed using a wet etch process that is selective for the first part of the polysilicon layer over the second part of the polysilicon layer.

13. The method of claim 8 wherein all of the second part of the polysilicon layer is converted into a metal silicide.

14. The method of claim 8 wherein the high-k gate dielectric layer comprises a material that is selected from the group consisting of hafnium oxide, zirconium oxide, and aluminum oxide, and the barrier layer comprises a metal nitride.

15. The method of claim 14 wherein the barrier layer comprises a material that is selected from the group consisting of titanium nitride and tantalum nitride.

16. A semiconductor device comprising:
a high-k gate dielectric layer that is formed on a substrate;
a barrier layer that is formed on the high-k gate dielectric layer; and
a fully silicided gate electrode that is formed on the barrier layer.

17. The semiconductor device of claim 16 wherein the barrier layer comprises a metal nitride, and the gate electrode comprises a metal silicide that is selected from the group consisting of nickel silicide, cobalt silicide, and titanium silicide.

18. The semiconductor device of claim 17 wherein the high-k gate dielectric layer comprises a material that is selected from the group consisting of hafnium oxide, zirconium oxide, and aluminum oxide, and the barrier layer comprises a material that is selected from the group consisting of titanium nitride and tantalum nitride.

19. The semiconductor device of claim 16 wherein the fully silicided gate electrode comprises a PMOS gate electrode, and further comprising a metal NMOS gate electrode.

20. The semiconductor device of claim 19 wherein
the metal NMOS gate electrode is between about 100 and about 2,000 angstroms thick, has a workfunction that is between about 3.9 eV and about 4.2 eV, and comprises a material that is selected from the group consisting of hafnium, zirconium, titanium, tantalum, aluminum, a metal carbide, and an aluminide; and
the PMOS gate electrode is between about 100 and about 2,000 angstroms thick, and has a workfunction that is between about 4.3 eV and about 4.8 eV.
